(19) United States
(12) Patent Application Publication
(10) Pub. No.: US 2026/0279725 A1
(43) Pub. Date: Sep. 17, 2026

(54) CHARGED PARTICLE BEAM DEVICE AND DEPOSITION METHOD

(71) Applicant: Kioxia Corporation, Tokyo (JP)

(72) Inventor: Mitsuo KOIKE, Mie, Mie (JP)

(73) Assignee: Kioxia Corporation, Tokyo (JP)

(21) Appl. No.: 19/317,721

(22) Filed: Sep. 3, 2025

(30) Foreign Application Priority Data
Mar. 17, 2025 (JP) 2025-042337

(51) Int. Cl. H01J 37/317; H01J 37/06; H01J 37/08

(52) U.S. Cl. CPC H01J 37/3178; H01J 37/06; H01J 37/08; H01J 2237/006; H01J 2237/30483

(57) ABSTRACT

A charged particle beam device includes a chamber configured to accommodate a target; a first beam generator configured to irradiate the target with a charged particle beam in a first direction; a first nozzle configured to introduce a first gas to the chamber for depositing a material on the target, the first nozzle extending toward a first position on the target being irradiated with the charged particle beam; and a second nozzle configured to introduce a rare gas to the chamber, the second nozzle extending toward a second position above the first position.

### CROSS-REFERENCE TO RELATED APPLICATION

This application is based upon and claims the benefit of priority from Japanese Patent Application No. 2025-042337, filed Mar. 17, 2025, the entire contents of which are incorporated herein by reference.

### FIELD

Embodiments described herein relate generally to a charged particle beam device and a deposition method.

### BACKGROUND

A deposition method of depositing materials on a target using a charged particle beam device is developed. However, in the charged particle beam, there is a problem that a deposition rate of the material is reduced when the target, which is a base of deposition, is an insulating material.

### DESCRIPTION OF THE DRAWINGS

FIG. 1 is a cross-sectional view showing a configuration example of a charged particle beam device according to the present embodiment.

FIG. 2 is a conceptual diagram showing an example of a deposition process according to the present embodiment.

FIG. 3 is a conceptual diagram showing in more detail a principle of a deposition method according to the present embodiment.

FIG. 4 is an explanatory view showing a phenomenon at a position P140 in the deposition method according to the present embodiment.

FIG. 5 is an explanatory view showing a phenomenon at a position Pm in the deposition method according to the present embodiment.

FIG. 6 is an explanatory view showing a phenomenon at a position P130 in the deposition method according to the present embodiment.

### DETAILED DESCRIPTION

In general, according to one embodiment, a charged particle beam device includes a chamber configured to accommodate a target; a first beam generator configured to irradiate the target with a charged particle beam in a first direction; a first nozzle configured to introduce a first gas to the chamber for depositing a material on the target, the first nozzle extending toward a first position on the target being irradiated with the charged particle beam; and a second nozzle configured to introduce a rare gas to the chamber, the second nozzle extending toward a second position above the first position.

Hereinafter, embodiments of the present disclosure will be described with reference to the drawings. The present embodiment does not limit the present disclosure. The drawings are schematic or conceptual. In the specification and drawings, the same elements are denoted by the same reference numerals.

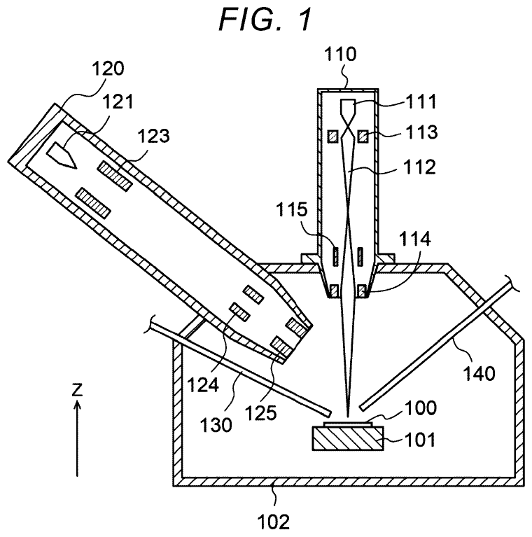

FIG. 1 is a cross-sectional view showing a configuration example of a charged particle beam device according to the present embodiment. A charged particle beam device (hereinafter, simply referred to as a beam device) 1 is a device that irradiates a target 100 with a charged particle beam in a chamber 102 to deposit a material. The beam device 1 may be a so-called focused ion beam (FIB) device. The beam device 1 may be used, for example, in a charged particle beam induced deposition process, a focused ion beam direct deposition, or a focused electron beam direct deposition.

The beam device 1 includes a stage 101, the chamber 102, beam generating units (or beam generators) 110 and 120, and gas nozzles 130 and 140.

The chamber 102 accommodates the target 100 and the stage 101, and an inside of the chamber 102 is depressurized by a vacuum pump (not shown). The stage 101 is capable of mounting the target 100. In addition, the stage 101 is movable within the chamber 102.

The beam generating unit 110 generates, for example, an ion beam 112 as an example of a charged particle beam. The beam generating unit 110 includes an ion source 111, a condenser lens 113, an objective lens 114, and a deflection coil 115. The beam generating unit 110 is disposed in a direction substantially perpendicular to a surface of the target 100 on which the material is deposited. The beam generating unit 110 focuses the ion beam 112 emitted from the ion source 111 and irradiates the target 100 with the ion beam 112 in a −Z direction. The ion source 111 generates and emits the ion beam 112 as a charged particle beam. The condenser lens 113 and the objective lens 114 focus the ion beam 112. The deflection coil 115 moves a position of the ion beam 112 to emit the ion beam 112 at any position. The beam device 1 can locally deposit the material at the irradiation position of the ion beam 112. The beam generating unit 110 may generate an electron beam as the charged particle beam. However, as will be described later, it is preferable that the charged particle beam is an ion beam.

The beam generating unit 120 includes an electron source 121, a condenser lens 123, an objective lens 124, and a deflection coil 125. The beam generating unit 120 is disposed in a direction inclined with respect to the surface of the target 100 on which the material is deposited. The beam generating unit 120 irradiates the target 100 with an electron beam. The electron source 121 generates and emits the electron beam. The condenser lens 123 and the objective lens 124 focus the electron beam. The deflection coil 125 moves a position of the electron beam to emit the electron beam at any position. The beam generating unit 120 may irradiate the target 100 with the electron beam together with the ion beam 112, but is not essential and may be omitted.

The gas nozzle 130 is inserted into the chamber 102 from an outside and extends to the vicinity of the target 100. The gas nozzle 130 introduces a material gas into the chamber 102 from the outside. The gas nozzle 130 extends toward the irradiation position on the target 100 to be irradiated with the ion beam 112. Therefore, the gas nozzle 130 ejects the material gas toward the irradiation position on the target 100 from an opening at a tip. The gas nozzle 130 extends in a direction inclined with respect to the surface of the target 100 on which a reaction product is deposited, and supplies the material gas from the inclined direction. A relative distance and a relative position between the gas nozzle 130 and the target 100 can be changed by an operation of the stage 101 or the gas nozzle 130. The gas nozzle 130 is shortened not to be in contact with the stage 101 when not in a deposition process.

The material gas is a raw material gas used to deposit the material on the target 100. The material gas is, for example, tungsten hexacarbonyl (W(CO)₆), naphthalene (C₁₀H₈), or tetraethyl orthosilicate (TEOS), (Si(OC₂H₅)₄) or the like. Tungsten hexacarbonyl (W(CO)₆) is used to deposit tungsten (W) on the target 100. Naphthalene (C₁₀H₈) is used to deposit carbon (C) on the target 100. TEOS (Si(OC₂H₅)₄) is used to deposit a silicon oxide (SiO₂) on the target 100. The material to be deposited on the target 100 is not limited to these.

The gas nozzle 140 is inserted into the chamber 102 from an outside and extends to the vicinity of the target 100. The gas nozzle 140 introduces an assist gas into the chamber 102 from the outside. An opening of the gas nozzle 140 is located upstream (+Z side) of the ion beam 112 with respect to an opening of the gas nozzle 130. The gas nozzle 140 extends toward a position upstream (+Z side) of the ion beam 112 with respect to the irradiation position on the target 100 to be irradiated with the ion beam 112. Accordingly, the gas nozzle 140 ejects the assist gas from the opening at the tip toward a position upstream (+Z side) of the ion beam 112 with respect to the irradiation position on the target 100. The gas nozzle 140 is extendable such that an opening of the gas nozzle 140 is positioned upstream of the charged particle beam with respect to an opening of the gas nozzle 130. In addition, when the material is deposited by an electron beam instead of the ion beam 112, a deposition surface of the target 100 is directed to the beam generating unit 120. In this case, the gas nozzle 140 is extendable such that the opening of the gas nozzle 140 is positioned upstream of the electron beam from the beam generating unit 120.

The assist gas is used to supply electrons, ionized from the assist gas by the ion beam 112, to the material gas. The assist gas is, for example, any of rare gases (He, Ne, Ar, Xe, and Kr).

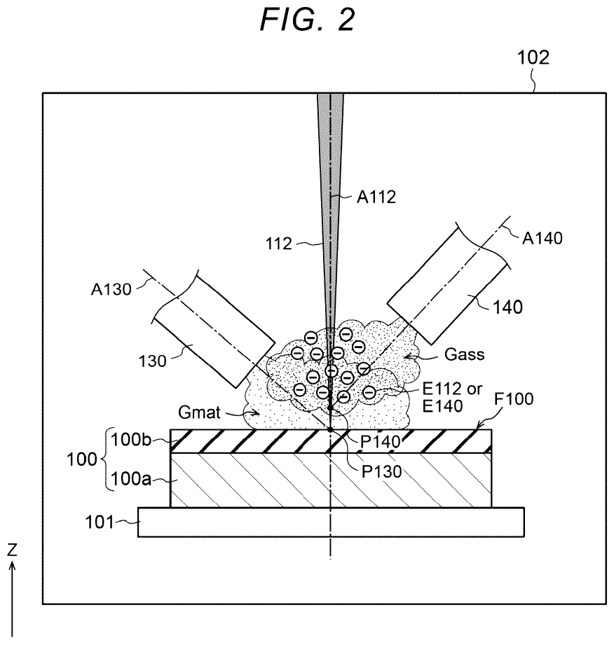

FIG. 2 is a conceptual diagram showing an example of a deposition process according to the present embodiment.

In the chamber 102, the target 100 is placed on the stage 101. The target 100 has a substrate 100a and the target film 100b. The substrate 100a may be, for example, a semiconductor substrate such as a silicon substrate, and may be an insulating material or a conductive material. The target film 100b is provided on the substrate 100a. The target film 100b is a base material on which a material is deposited. For the target film 100b, for example, an insulating material, such as a silicon oxide film, a silicon nitride film, or a polyimide, is used.

The beam generating unit 110 in FIG. 1 irradiates the target film 100b with the ion beam 112. An irradiation port of the ion beam 112 of the beam generating unit 110 faces a deposition surface F100 of the target film 100b in a substantially perpendicular direction. The beam generating unit 110 is configured to scan while irradiating the deposition surface F100 with the ion beam 112.

The gas nozzle 130 introduces a material gas Gmat toward an irradiation position P130 on the target film 100b on which the ion beam 112 is emitted. The irradiation position P130 is, for example, an intersection between a central axis (an optical axis of the ion beam 112) A112 of the beam generating unit 110 and the deposition surface F100. In this case, the irradiation position P130 is an intersection of the central axis A112 of the beam generating unit 110, the deposition surface F100, and a central axis A130 of the gas nozzle 130. The material gas Gmat is supplied to an irradiation region on the deposition surface F100 substantially uniformly by introducing the material gas Gmat toward the irradiation position P130 from a direction inclined with respect to the deposition surface F100 by the gas nozzle 130. The intersection between the central axis A112 of the beam generating unit 110 and the central axis A130 of the gas nozzle 130 may not necessarily strictly coincide with the irradiation position P130 at which the ion beam 112 is emitted on the target film 100b, depending on a scanning position of the ion beam 112 on the deposition surface F100.

The gas nozzle 140 introduces an assist gas Gass toward a position P140 upstream (+Z side) of the ion beam 112 with respect to the irradiation position P130. The position P140 is an intersection between the central axis A112 of the beam generating unit 110 and the central axis A140 of the gas nozzle 140. The assist gas Gass is ionized by being irradiated with the ion beam 112 and supplies electrons to the material gas Gmat. The electrons ionized from the assist gas Gass dissociate the material gas Gmat together with the electrons of the ion beam 112. The dissociated material gas Gmat is deposited on the target film 100b as a deposition material. As described above, the assist gas Gass is used to supply ionized electrons and is an auxiliary gas for promoting a dissociation reaction of the material gas Gmat.

The gas nozzle 140 supplies the assist gas Gass to the position P140 upstream of the irradiation position P130. As a result, a large amount of the assist gas Gass is present to be concentrated above the material gas Gmat (+Z direction), and the mixing of the assist gas Gass with the material gas Gmat in the vicinity (directly above) of the deposition surface F100 is inhibited to some extent. By inhibiting the mixing of the assist gas Gass and the material gas Gmat, the material gas Gmat in the vicinity of the deposition surface F100 is not significantly diluted by the assist gas Gass, and the decrease in the partial pressure of the material gas Gmat in the vicinity of the deposition surface F100 may be inhibited.

As described above, according to the present embodiment, the assist gas Gass is introduced to the position P140 upstream of the irradiation position P130, and thus the ionized electrons from the assist gas Gass are added to the irradiation electrons from the ion beam 112 while maintaining a high partial pressure of the material gas Gmat in the vicinity of the deposition surface F100. As a result, the dissociation reaction of the material gas Gmat is promoted, and even when the target film 100b is an insulating film as will be described later, a decrease in the deposition rate of the material can be prevented.

It is preferable that the material gas Gmat and the assist gas Gass are introduced into the chamber 102 simultaneously. Accordingly, at the time of the irradiation of the ion beam 112, the deposition of the material can be started simultaneously with the supply of the ionized electrons from the assist gas Gass and the irradiation electrons from the ion beam 112. The timing of introduction of the material gas Gmat and the assist gas Gass may be slightly shifted before and after, and the effect of the present embodiment can be obtained.

It is preferable that the timing of the start of irradiation of the ion beam 112 is the same as the timing of the introduction of the material gas Gmat and the assist gas Gass. The effect of the present embodiment can be also obtained even when the timing of the start of the irradiation of the ion beam 112 is slightly shifted before and after the introduction of the material gas Gmat and the assist gas Gass.

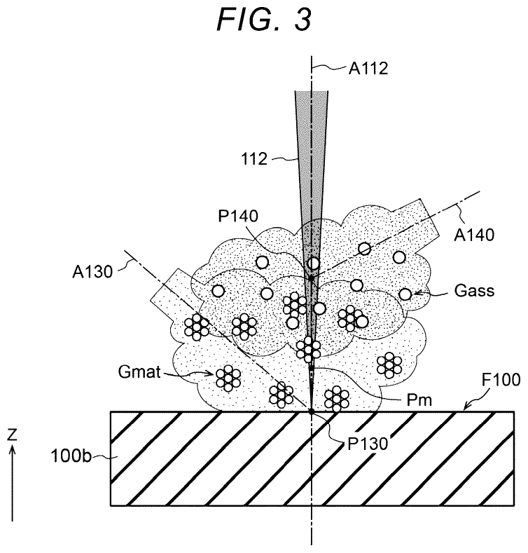

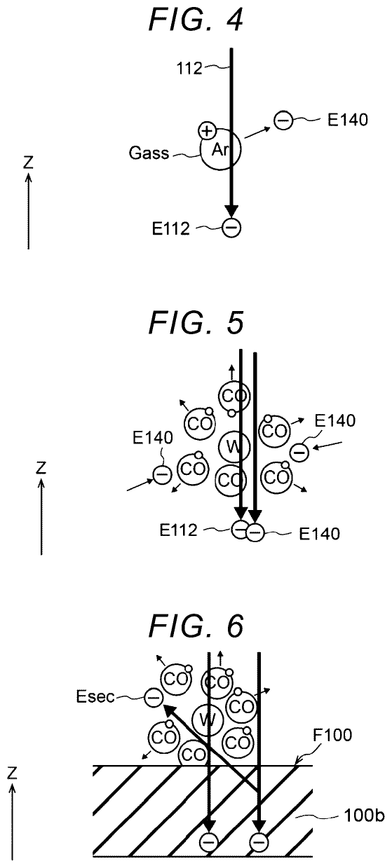

FIG. 3 is a conceptual diagram showing a principle of a deposition method according to the present embodiment. FIG. 4 is an explanatory view showing a phenomenon at the position P140. FIG. 5 is an explanatory view showing a phenomenon at a position Pm. FIG. 6 is an explanatory view showing a phenomenon at the position P130. FIGS. 3 to 6 show a deposition process of tungsten (W) as an example. In addition, as an example of the assist gas Gass, argon (Ar) is used. The position Pm is located on the central axis A112 between the position P130 and the position P140.

The material gas Gmat is introduced toward the irradiation position P130. The assist gas Gass is introduced toward the position P140 above the irradiation position P130. Therefore, the assist gas Gass and the material gas Gmat are substantially in a two-layer state, although the assist gas Gass and the material gas Gmat are mixed to some extent on the deposition surface F100 of the target film 100b.

When the ion beam 112 is emitted, at the position P140, as shown in FIG. 4, the ion beam 112 irradiates the argon of the assist gas Gass, and the argon is ionized. The argon is ionized to generate an ionized electron E140. The ionized electrons E140 move in a direction (−Z direction) of the target film 100b (that is, the material gas Gmat) together with the ionized electrons E112 from the ion beam 112 by the voltage (for example, positive voltage) of the stage 101.

At the position Pm in FIG. 3, as shown in FIG. 5, not only the ionized electrons E112 but also the ionized electrons E140 dissociate the tungsten hexacarbonyl (W(CO)₆) of the material gas Gmat. That is, both the ionized electron E112 and the ionized electron E140 dissociate CO of the tungsten hexacarbonyl (W(CO)₆) from tungsten (W).

At the position P130 in FIG. 3, as shown in FIG. 6, secondary electrons Esec, which are generated when the ionized electrons E112 and the ionized electrons E140 collide with the target film 100b, further promote the dissociation of the tungsten hexacarbonyl of the material gas Gmat. Accordingly, tungsten is deposited on the deposition surface F100 of the target film 100b.

However, when the target film 100b is an insulating film, the secondary electrons Esec generated when the target film 100b is irradiated with electrons are less than those of a conductive film. Therefore, when the material is deposited on the insulating film only by the ionized electrons E112 of the ion beam 112, the dissociation of the material gas Gmat enters a slow mode, and the deposition rate of the material is reduced.

Meanwhile, according to the present embodiment, not only the ionized electrons E112 of the ion beam 112 but also the ionized electrons E140 of the assist gas Gass dissociate the material gas Gmat. Therefore, even when the target film 100b is an insulating material having a small amount of secondary electron generation, the ionized electrons E140 of the assist gas Gass can assist the dissociation of the material gas Gmat to prevent a decrease in the deposition rate of the material. That is, the deposition efficiency can be maintained. Accordingly, the deposition rate of the material can be stabilized independent of the material of the target film 100b.

The assist gas Gass is preferably a rare gas that does not react with the material gas Gmat and the element in the chamber 102 (stable), and can be ionized by the ion beam 112. In this case, since the assist gas Gass is present to be concentrated above the material gas Gmat (+Z direction) in the chamber 102 without reacting with the material gas Gmat, it is difficult to incorporate the components of the assist gas Gass during the deposition process, and it is possible to deposit the material on the target film 100b without substantially containing the components of the assist gas Gass. In addition, the assist gas Gass is preferably an element having a large atomic weight (a large collision area) that can efficiently generate the ionized electrons E140 (a large amount). Therefore, for the assist gas Gass, neon is more preferable than helium, and argon, krypton, and xenon are more preferable than neon. Considering not only the atomic weight but also the cost and the like, it can be said that argon and xenon are preferable as the assist gas Gass.

In addition, in the present embodiment, the ion beam 112 is used as an example of the charged particle beam. However, the charged particle beam may be an electron beam. However, since the mass of the ion beam 112 is larger than that of the electron beam, the assist gas Gass can be efficiently ionized. Therefore, from the viewpoint of the deposition efficiency, it can be said that the ion beam 112 is preferable to the electron beam as the charged particle beam.

When the material gas Gmat is, for example, naphthalene (C₁₀H₈), the ionized electron E112 and the ionized electron E140 dissociate hydrogen from naphthalene and deposit carbon (C) on the deposition surface F100 of the target film 100b.

For example, when the material gas Gmat is TEOS (Si(OC₂H₅)₄), the ionized electron E112 and the ionized electron E140 dissociate C₂H₅ and oxygen from TEOS, and deposit a silicon oxide (SiO₂) on the deposition surface F100 of the target film 100b.

In addition, in the above embodiment, the material gas Gmat and the assist gas Gass are introduced separately, but the material gas Gmat and the assist gas Gass may be mixed and introduced simultaneously. In this case, the partial pressure of the material gas Gmat on the deposition surface F100 of the target film 100b is reduced. However, the ionized electrons E140 of the assist gas Gass can compensate the dissociation of the material gas Gmat, and thus the overall decrease in the deposition rate of the material can be prevented. Therefore, even when the material gas Gmat and the assist gas Gass are mixed and supplied, the effect of the present embodiment is not lost.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A charged particle beam device comprising:
a chamber configured to accommodate a target;
a first beam generator configured to irradiate the target with a charged particle beam in a first direction;
a first nozzle configured to introduce a first gas to the chamber for depositing a material on the target, the first nozzle extending toward a first position on the target being irradiated with the charged particle beam; and
a second nozzle configured to introduce a rare gas to the chamber, the second nozzle extending toward a second position above the first position.

2. The charged particle beam device according to claim 1,
wherein the first nozzle introduces the first gas into the chamber and the second nozzle introduces the rare gas into the chamber simultaneously.

3. The charged particle beam device according to claim 1,
wherein the first beam generator is disposed in a direction substantially perpendicular to a surface of the target.

4. The charged particle beam device according to claim 1,
wherein the first beam generator is configured to scan a surface of the target with the charged particle beam.

5. The charged particle beam device according to claim 1,
wherein the charged particle beam is an ion beam.

6. The charged particle beam device according to claim 5, further comprising:
a second beam generator configured to irradiate the target with an electron beam.

7. The charged particle beam device according to claim 6,
wherein the second beam generator is disposed in a direction inclined with respect to a surface of the target.

8. The charged particle beam device according to claim 1,
wherein the rare gas is ionized by the charged particle beam to supply electrons to the first gas.

9. A deposition method comprising:
irradiating a target accommodated in a chamber with a charged particle beam;
introducing, into the chamber, a first gas and a rare gas on the target; and
depositing a reaction product of the first gas on the target to be irradiated with the charged particle beam, without substantially containing a component of the rare gas.

10. The deposition method according to claim 9,
wherein the first gas is introduced into the chamber through a first nozzle, and
the rare gas is introduced into the chamber through a second nozzle different from the first nozzle.

11. The deposition method according to claim 9,
wherein the first gas is supplied to the target from a direction inclined with respect to a surface of the target on which the reaction product is deposited.

12. The deposition method according to claim 9,
wherein the first gas is introduced toward a first position on the target being irradiated with the charged particle beam, and the rare gas is introduced toward a second position above the first position.

13. The deposition method according to claim 9,
wherein the first gas and the rare gas are introduced into the chamber simultaneously.

14. The deposition method according to claim 9,
wherein the charged particle beam is scanned over a surface of the target on which the reaction product is deposited and the target is irradiated with the charged particle beam.

15. The deposition method according to claim 9,
wherein the charged particle beam is an ion beam.

16. The deposition method according to claim 15, further comprising:
irradiating the target with an electron beam.

17. The deposition method according to claim 9,
wherein the rare gas is ionized by the charged particle beam to supply electrons to the first gas.

18. The deposition method according to claim 12, wherein the rare gas is argon or xenon.

19. The deposition method according to claim 9,
wherein the first gas is any one of tungsten hexacarbonyl (W(CO)₆), naphthalene (C₁₀H₈), or TEOS (Si(OC₂H₅)₄).

20. The deposition method according to claim 9,
wherein an insulating film as the target is irradiated with the charged particle beam.
